(19) United States
(12) Patent Application Publication
(10) Pub. No.: US 2026/0245824 A1
(43) Pub. Date: Aug. 20, 2026

(54) Transport Package for Charged Particle Gun and Maintenance Method for Charged Particle Gun

(71) Applicant: Hitachi High-Tech Corporation, Minato-ku, Tokyo (JP)

(72) Inventors: Shuhei NAKASHIMA, Tokyo (JP); Masahiro Fukuta, Tokyo (JP); Yuki Jokoji, Tokyo (JP); Masayuki Fukumoto, Tokyo (JP)

(21) Appl. No.: 18/991,871

(22) Filed: Dec. 23, 2024

(30) Foreign Application Priority Data
Feb. 1, 2024 (JP) 2024-014185

(51) Int. Cl. H01J 3/02; H01J 3/04

(52) U.S. Cl. CPC H01J 3/028; H01J 3/026; H01J 3/04

(57) ABSTRACT

Provided is a transport package that performs start-up and performance evaluation of a charged particle gun in the outside of a charged particle beam device.

A transport package for a charged particle gun includes an installation unit that is capable of installing a charged particle gun therein, vacuum evacuation equipment that is capable of making the inside of the charged particle gun into a vacuum state, in a state where the charged particle gun is installed in the installation unit, evaluation equipment that is capable of evaluating at least one of performance of the charged particle gun or performance of a charged particle beam irradiated from the charged particle gun in the state where the charged particle gun is installed in the installation unit. In the state where the charged particle gun is installed in the installation unit, the installation unit, the vacuum evacuation equipment, and the evaluation equipment can be moved together.

### TECHNICAL FIELD

The present invention relates to a transport package for a charged particle gun and a maintenance method for the charged particle gun.

### BACKGROUND ART

A charged particle beam device includes a charged particle gun on which a charged particle source for generating charged particle beams is installed. In a case where the charged particle beam device is, for example, a scanning electron microscope (SEM), the scanning electron microscope includes an electron gun on which an electron source for generating electron beams is installed.

In this type of charged particle source of the charged particle gun, when performing replacement or maintenance, all or part of the charged particle gun is removed from the charged particle beam device. After performing the replacement or maintenance, in the charged particle beam device, readjustment and performance check of the charged particle gun are required in a vacuum state.

For example, PTL 1 discloses a test device provided with a chamber for installing an ion source that is a target for maintenance operation. In this test device, tests are performed to evaluate the performance of the ion source with the inside of the chamber in a vacuum evacuated state.

### CITATION LIST

### Patent Literature

PTL 1: J2667205B

### SUMMARY OF INVENTION

### Technical Problem

PTL 1 focuses on evaluating the performance of the ion source in a vacuum evacuated state, but does not mention start-up of the ion gun or confirmation of the performance of the ion gun, which are necessary during maintenance of the ion gun.

When starting the maintenance of the charged particle gun, it takes time to restore the charged particle beam to a controllable state, resulting in generating downtime for the charged particle beam device. In a case of maintenance such as replacing the charged particle source and installing a new charged particle source, a long period of operation time is required, since it is necessary to release the atmospheric pressure, remove the charged particle gun from the charged particle beam device, prepare a new charged particle gun, bake the new charged particle gun in a vacuum state, and then make the inside of the new charged particle gun into an extremely high vacuum state.

A main object of the present application is to provide a transport package that performs start-up and performance evaluation of the charged particle gun disconnect from the charged particle beam device and in a separate location. In addition, by this transport package, the time it takes to restart the charged particle beam device is shortened and the uptime of the charged particle beam device is improved.

Other objects and new features will become apparent from the description of this specification and the accompanying drawings.

### Solution to Problem

A transport package for a charged particle gun according to one embodiment includes an installation unit that is capable of installing a charged particle gun therein, vacuum evacuation equipment that is capable of making the inside of the charged particle gun into a vacuum state, in a state where the charged particle gun is installed in the installation unit, evaluation equipment that is capable of evaluating at least one of performance of the charged particle gun or performance of the charged particle beam irradiated from the charged particle gun in the state where the charged particle gun is installed in the installation unit. In the state where the charged particle gun is installed in the installation unit, the installation unit, the vacuum evacuation equipment, and the evaluation equipment can be moved together.

A maintenance method for a charged particle gun according to one embodiment includes the steps of (a) transporting a transport package including a second charged particle gun, of which the inside is maintained in a vacuum state, to the vicinity of a first charged particle beam device; (b) after the step (a), replacing a first charged particle gun provided in the first charged particle beam device with the second charged particle gun; (c) after the step (b), installing the first charged particle gun in the transport package; (d) after the step (c), making the inside of the first charged particle gun into a vacuum state in the transport package; and (e) after the step (d), performing performance evaluation of the first charged particle beam irradiated from the first charged particle gun or performance evaluation of the first charged particle gun in the transport package.

A maintenance method for a charged particle gun according to another embodiment includes the steps of (a) transporting a first transport package including a second charged particle gun, of which the inside is maintained in a vacuum state, and one or more transport packages other than the first transport package, to the vicinity of a first charged particle beam device; (b) after the step (a), installing a first charged particle gun provided in the first charged particle beam device in any one of the one or more transport packages; (c) after the step (b), mounting the second charged particle gun on the first charged particle beam device from the first transport package; (d) after the step (c), making the inside of the first charged particle gun into a vacuum state in the transport package having the first charged particle gun installed therein, among the one or more transport packages; and (e) after the step (d), performing performance evaluation of the first charged particle beam irradiated from the first charged particle gun or performance evaluation of the first charged particle gun, in the transport package having the first charged particle gun installed therein.

### Advantageous Effects of Invention

According to one embodiment, it is possible to provide a transport package that is capable of performing start-up and performance evaluation of the charged particle gun in the disconnect from the charged particle beam device and in a separate location. In addition, by this transport package, it is possible to shorten the time it takes to restart the charged particle beam device and to improve the operating rate of the charged particle beam device.

### BRIEF DESCRIPTION OF DRAWINGS

FIG. 1 is a schematic view illustrating a transport package for a charged particle gun in a first embodiment.

FIG. 2 is a schematic view illustrating an equipment unit and vacuum evacuation equipment in the first embodiment.

FIG. 3 is a schematic view illustrating an electrical connection relationship between an electron gun, an installation unit, and evaluation equipment in the first embodiment.

FIG. 4 is a schematic view illustrating a protective cover in the first embodiment.

FIG. 5 is a flow diagram illustrating a maintenance method for a charged particle gun performed using the transport package in the first embodiment.

FIG. 6 is a flow diagram illustrating a maintenance method for a charged particle gun performed using a transport package in a first modification.

FIG. 7 is a schematic view illustrating a charged particle beam device and a transport package for a charged particle gun in a second modification.

### DESCRIPTION OF EMBODIMENTS

Hereinafter, the embodiment will be described in detail with reference to the drawings. In addition, in all the drawings for describing the embodiments, the same reference numerals are used for members having the same functions, and the repeated descriptions thereof will be omitted. In addition, in the following embodiments, unless otherwise necessary, the same or similar parts will not be described repeatedly.

In addition, in the following description of the embodiment, an example in which the present disclosure is applied to a scanning electron microscope (SEM) using an electron beam as a charged particle beam device is shown. However, this embodiment should not be interpreted as being limited, and the disclosure may be applied to, for example, an apparatus that uses a charged particle beam such as an ion beam, or a general observation apparatus.

Examples of performance of the electron beam (charged particle beam) include the current amount of electron beam, current stability, electron beam energy, electron beam fluctuation, flares, gas adsorption to the electron source, and X-rays.

The evaluation equipment may evaluate the performance of an electron gun (charged particle gun). The performance of the electron gun includes the degree of vacuum, vibration characteristics, and voltage resistance.

In addition, the evaluation equipment refers to at least one of a detector or a measuring device. The physical quantity that the detector or measuring device targets is not limited to the above-mentioned examples of the performance of the electron beam or the example of the performance of the electron gun. Further, the evaluation equipment can be installed either inside or outside a vacuum.

Examples of the detector include a Faraday cup, a photomultiplier tube, and a precision resistor. Examples of the measuring devices include an ammeter, a voltmeter, and a tester. Furthermore, in this application, parts or equipment having a measuring function, such as a circuit or an electronic calculator, are also considered as the measuring devices. In this application, the term “measuring device” also includes devices that display any physical quantity.

In this application, evaluation refers to the act of measuring one or more physical quantities, or the act of displaying the results or values of a measurement. Examples of the physical quantities that are subject to evaluation include current values and voltage values. The evaluation in this application is not limited to the performance of the electron beam or the performance of the electron gun described above. Note that the physical quantities are listed only as examples, and other physical quantities may be used.

The evaluation in this application is not limited to direct evaluation of a desired physical quantity, but also includes indirect evaluation.

The direct evaluation refers to direct evaluation of the desired physical quantity. In the direct evaluation, the physical quantities at the time of detection and after evaluation do not change. For example, the direct evaluation can be performed by measuring the current amount of the electron beam using a Faraday cup and an ammeter. In this case, the physical quantity at the time of detection is the current amount, and the physical quantity after evaluation is also the current amount.

The indirect evaluation refers to the calculation of a desired physical quantity from another physical quantity, and refers to a case where the physical quantity at the time of detection and the physical quantity after evaluation are converted at least once during the process from detection to evaluation.

One example of the indirect evaluation is to convert the current amount of electron beams into a current value by measuring the voltage change across a precision resistor. At this time, the current at the time of detection is converted into the current amount after evaluating a different physical quantity, the voltage value, on the way conversion. Another example of the indirect evaluation is a method in which a phosphor or a photomultiplier tube is used and the output voltage value is converted into the current amount of the electron beam. In this case, the physical quantity of the phosphor's light emission intensity is evaluated as a voltage, and then that voltage value is converted into a different current value called the current amount. In this way, when there is a transformation of one or more physical quantities, it is considered an indirect evaluation. In the indirect evaluation, the physical quantity at the time of detection and the physical quantity after evaluation may be the same.

For the purposes of evaluation in this patent, the detector and measuring device do not need to be directly connected at all times, nor do they need to be contiguous in time. For example, when evaluating the electron beam by voltage drop of the precision resistor, a test pin is prepared in advance in the evaluation equipment, and the voltage value is evaluated by applying a tester to the test pin during evaluation. As another example, the detected physical quantity may be temporarily stored in a logger or a personal computer, and the current amount or the like may be evaluated based on the processed results at a later date.

Furthermore, the physical quantities obtained by the evaluation may be displayed in any form, for example, in a form in which values are displayed in real time, in a form in which values are displayed as one-dimensional data using a logger, or in a form in which values are displayed in two or more dimensions using a personal computer. In addition, the physical quantity obtained by the evaluation may be amplified by an amplifier or the like at a rear stage of the detector.

### FIRST EMBODIMENT

### Transport Package for Charged Particle Gun

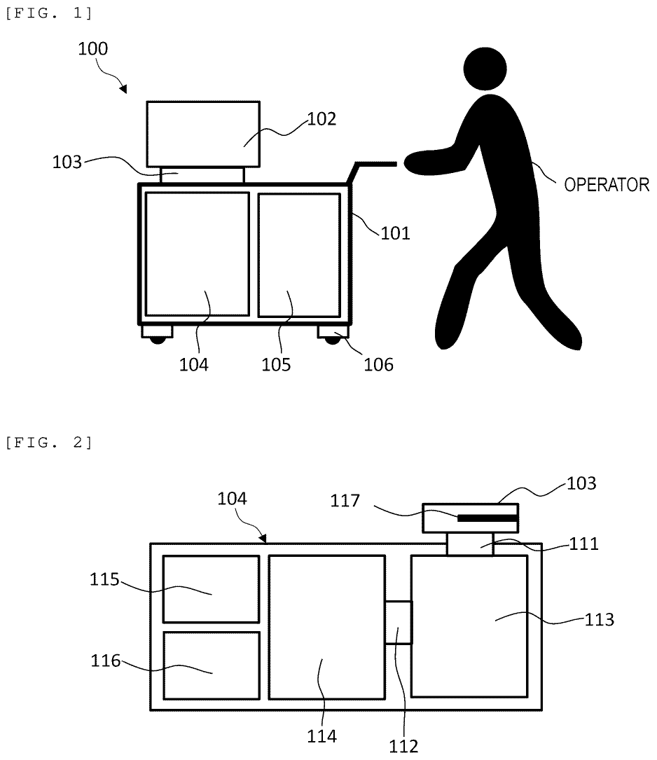

Hereinafter, each structure provided in a transport package 100 according to a first embodiment will be described with reference to FIG. 1. In the first embodiment, a scanning electron microscope (SEM device) is given as an example of a charged particle device that is a target of the transport package 100. In addition, a charged particle gun included in the charged particle device is, for example, an electron gun, a charged particle source included in the charged particle gun is, for example, an electron source, and a charged particle beam irradiated from the charged particle gun is, for example, an electron beam.

As illustrated in FIG. 1, the transport package 100 includes an installation unit 103, vacuum evacuation equipment 104, and evaluation equipment 105.

The installation unit 103 can install an electron gun (charged particle gun) 102 therein. The vacuum evacuation equipment 104 can make the inside of the electron gun 102 into a vacuum state in a state where the electron gun 102 is installed in the installation unit u 103. The evaluation equipment 105 can evaluates performance of the electron gun 102 or performance of the electron beam (charged particle beam) irradiated from the electron gun 102 in the state where the electron gun 102 is installed in the installation unit 103.

Note that, in the present specification, a phrase of “the electron gun 102 is installed in the transport package 100” means that “the electron gun 102 is installed in the installation unit 103”.

In the transport package 100, in the state where the electron gun 102 is installed in the installation unit 103, the installation unit 103, the vacuum evacuation equipment 104, and the evaluation equipment 105 can be moved together. In order to move these all together, the transport package 100 may include mobile equipment 101. The mobile equipment 101 is, for example, a trolley, and has casters 106 for making the trolley movable. Other examples of the mobile equipment 101 include hovercraft or conveyors. The transport package 100 may include vibration isolation equipment such as air suspension.

The mobile equipment 101 can be mounted with the installation unit 103, the vacuum evacuation equipment 104, and the evaluation equipment 105. For example, when an operator operates the mobile equipment 101, the mobile equipment 101 can move the installation unit 103, the vacuum evacuation equipment 104, and the evaluation equipment 105, in the state where the electron gun 102 is installed in the installation unit 103. For example, it is possible to move the transport package 100 to the vicinity of a first SEM device, or to move the transport package 100 to the vicinity of a second SEM device from the first SEM device.

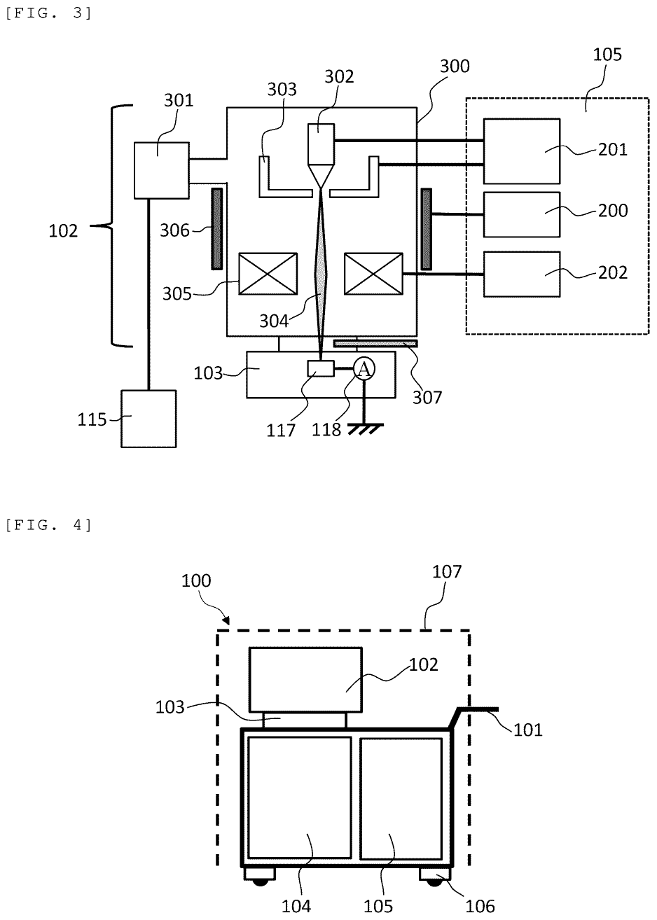

The relationship between the installation unit 103 and the vacuum evacuation equipment 104 will be described below with reference to FIG. 2. As illustrated in FIG. 2, the vacuum evacuation equipment 104 includes a pipe 111, a pipe 112, a turbo molecular pump 113, a diaphragm pump 114, an ion pump power supply 115, and a backup battery 116.

The installation unit 103 and the turbo molecular pump 113 are communicated with each other through the pipe 111. The turbo molecular pump 113 and the diaphragm pump 114 are communicated with each other through the pipe 112. Although not shown, the pipe 111 communicates with the inside of the installation unit 103, and when the electron gun 102 is installed in the installation unit 103, the pipe 111 can communicate with the inside of the electron gun 102 through the inside of the installation unit 103.

The inside of the electron gun 102 installed in the installation unit 103 is vacuum evacuated by the diaphragm pump 114 to a vacuum state of, for example, 10⁻¹ Pa or less. In addition, the inside of the electron gun 102 installed in the installation unit 103 is vacuum evacuated by the turbo molecular pump 113 to a vacuum state of, for example, 10⁻⁴ Pa or less.

Note that both of the turbo molecular pump 113 and the diaphragm pump 114 are not necessarily required, and if the inside of the electron gun 102 can be made in a certain degree of vacuum state with only one of them, only one of them may be provided in the vacuum evacuation equipment 104.

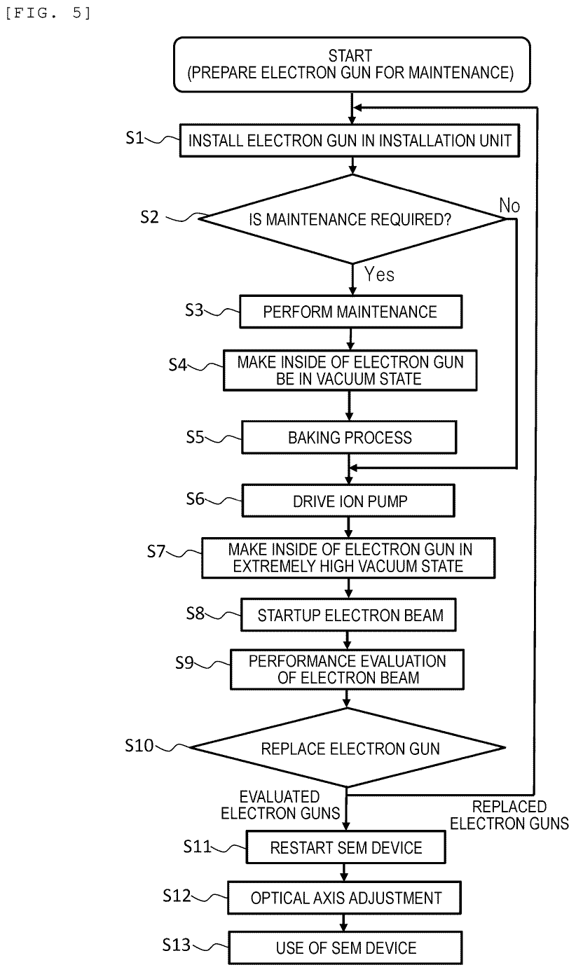

As illustrated in FIG. 3 described below, the electron gun 102 includes an ion pump 301. The ion pump power supply 115 is used to drive the ion pump 301. When the electron gun 102 is installed in the installation unit 103, the ion pump power supply 115 is electrically connected to the ion pump by a cable or the like (not shown). In addition, the electron gun 102 may include a Getter pump. Examples of the Getter pump include an NEG (Non-Evaporable Getter) pump.

By driving the ion pump 301 under the control of the ion pump power supply 115, the inside of the electron gun 102 can be evacuated to a vacuum. By using the ion pump 301, the inside of the electron gun 102 is kept at a lower pressure than when the turbo molecular pump 113 and the diaphragm pump 114 are used, and is kept at a Vacuum state (extremely high vacuum state) of, for example, 10⁻⁸ Pa or less. If the ion pump 301 is operable, the diaphragm pump 114 and the turbo molecular pump 113 are not necessarily required, and only the ion pump power supply 115 may be provided.

The backup battery 116 is electrically connected to the ion pump power supply 115. Even if the main power supply for the ion pump is stopped, the ion pump can be driven by using the backup battery 116 and the ion pump power supply 115. This allows the inside of the electron gun 102 to be kept in an extremely high vacuum state.

The electron gun 102, the installation unit 103, and the evaluation equipment 105 will be described below with reference to FIG. 3. As illustrated in FIG. 3, the evaluation equipment 105 includes a drive mechanism 200 for a heat mechanism 306, a high voltage power supply 201, and a power supply 202. The power supply 202 is, for example, a constant current power supply or a constant voltage power supply. The drive mechanism 200 is, for example, a baking power supply. The drive mechanism 200 may be a transformer or voltage regulator such as a slidac (variable autotransformer) that transforms the output voltage in addition to the baking power supply.

The electron gun 102 includes a housing 300, the ion pump 301, an electron source (charged particle source) 302, an acceleration electrode 303, a beam focusing mechanism 305, the heat mechanism 306, and a valve 307. The ion pump 301, the electron source 302, the acceleration electrode 303, and the beam focusing mechanism 305 are provided in the housing 300. The heat mechanism 306 and the valve 307 are provided in the outside of the housing 300. The heat mechanism 306 is a heater and for example, an electric heater. The heater is covered with an insulating material to improve heating efficiency in some cases. A heat insulating mechanism for improving the heating efficiency is also included in the heat mechanism 306. A temperature control mechanism is also included in the heat mechanism.

Note that the electron gun 102 in FIG. 3 is an example, and the beam focusing mechanism 305 and the heat mechanism 306 are not necessarily required.

In this specification, “the inside of the electron gun 102” may be used, but this means “the inside of the housing 300”.

When the electron gun 102 is installed in the installation unit 103, the drive mechanism 200 is electrically connected to the heat mechanism 306 by a cable or the like (not shown). By controlling the drive mechanism 200 to drive the heat mechanism 306, the temperature of the entire electron gun 102 can be adjusted.

When the electron gun 102 is installed in the installation unit 103, the high voltage power supply 201 is electrically connected to the electron source 302 and the acceleration electrode 303 by a cable or the like (not shown). Under the control of the high voltage power supply 201, an electron beam (charged particle beam) 304 is generated from the electron source 302, and the electron beam 304 is accelerated by applying a strong electric field from the acceleration electrode 303, and the electron beam 304 is irradiated from the electron gun 102.

When the electron gun 102 is installed in the installation unit 103, the power supply 202 is electrically connected to the beam focusing mechanism 305 by a cable or the like (not shown). The beam focusing mechanism 305 is a condenser lens such as an electromagnet with a coil, or an electrostatic lens with electrodes. By controlling the power supply 202 to drive the beam focusing mechanism 305, a magnetic field is generated from the beam focusing mechanism 305, and the electron beam 304 can be focused by the magnetic field. In addition, it is not necessary to focus the electron beam 304 using the beam focusing mechanism 305.

The installation unit 103 includes a detector 117 and a measuring device 118. The measuring device 118 is electrically connected to the detector 117. When the electron beam 304 is detected by the detector 117, the characteristics of the electron beam 304 can be measured by the measuring device 118.

An example of the detector 117 is a Faraday cup. An example of the measuring device 118 is an ammeter. When the Faraday cup and the ammeter are used, the amount of electron beam 304 that reaches the Faraday cup can be measured as a current value by the ammeter.

The detector 117 may be an electron beam detector instead of the Faraday cup. Examples of the electron beam detector include a phosphor, a photomultiplier tube, or a semiconductor detector. In addition, a configuration of the detector 117 may include signal amplification by an amplifier.

The locations of the detector 117 and the measuring device 118 are not necessarily limited those illustrated in FIG. 3. For example, the detector 117 and the measuring device 118 can be disposed at the end of the electron beam 304 after it has been bent by a lens or a deflector, allowing the characteristics of the electron beam 304 to be evaluated. In addition, the number of detectors 117 may be one or more, and multiple detectors 117 may be disposed in different locations.

The valve 307 can be controlled to be opened or closed between the electron gun 102 and the installation unit 103. The form of the valve 307 is not particularly limited, but for example, the valve is a compressed air vacuum valve. In the compressed air vacuum valve, an air intake that opens the compressed air vacuum valve when the compressed air is sent, and an air intake that closes the compressed air vacuum valve when the compressed air is sent. By dividing the air supply direction, the opened and closed states of the compressed air vacuum valve can be switched. In addition, when the compressed air vacuum valve is applied as the valve 307, the vacuum evacuation equipment 104 or the evaluation equipment 105 is provided with a compressor for sending compressed air.

When the valve 307 is opened, the inside of the electron gun 102 can be made into a vacuum state by the vacuum evacuation equipment 104. Also, when the valve 307 is opened, the electron beam 304 irradiated from the electron gun 102 can reach the inside of the installation unit 103 and reach the detector 117.

When removing the electron gun 102 from the installation unit 103, the valve 307 is closed. This allows the electron gun 102 to be replaced while the inside of the electron gun 102 is maintained in a vacuum state.

However, when moving within a room where air cleanliness is ensured, such as a clean room, or when moving in and out of the room, there is a risk that foreign matters such as floating fine particles may adhere to the electron gun 102, the installation unit 103, the vacuum evacuation equipment 104, and the evaluation equipment 105. To prevent such foreign matters, the transport package 100 may include a protective cover 107.

As illustrated in FIG. 4, the protective cover 107 can cover the installation unit 103, the vacuum evacuation equipment 104, and the evaluation equipment 105, and can be attached to and detached from the installation unit 103, the vacuum evacuation equipment 104, and the evaluation equipment 105. When the electron gun 102 is installed in the installation unit 103, the protective cover 107 can also cover the electron gun 102. In addition, the protective cover 107 may be applied to cover all or part of the mobile equipment 101.

### Maintenance Method for Charged Particle Gun

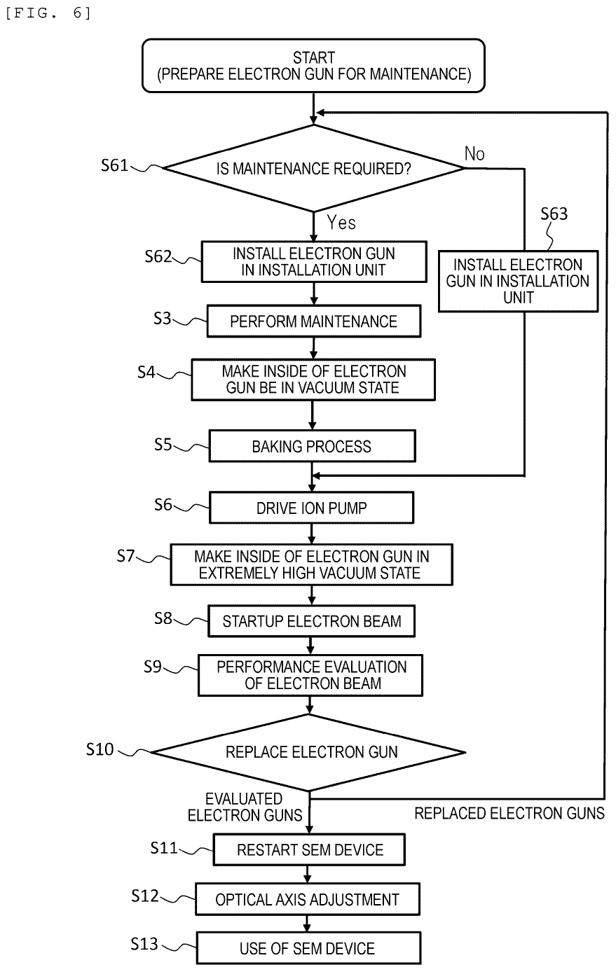

A maintenance method for a charged particle gun using the transport package 100 will be described below with reference to FIG. 5. The maintenance method for the charged particle gun includes steps S1 to S13 illustrated in FIG. 5.

A case is shown in which maintenance is performed on the electron guns 102 of a first SEM device and a second SEM device located at a location distant from the first SEM device.

First, the transport package 100 with the electron gun 102 for replacement, the inside of which is kept in a vacuum state, is transported to the vicinity of the first SEM device. This electron gun 102 for replacement is an electron gun that has undergone steps S1 to S9, which will be described later. Next, the electron gun 102 provided in the first SEM device is replaced with the electron gun 102 for replacement. Steps S1 to S13 are performed on the replaced electron gun 102 of the first SEM device.

In step S1, the electron gun 102 is installed in the transport package 100 (installation unit 103).

In step S2, it is determined whether maintenance is required for the electron gun 102 installed in the installation unit 103. If the maintenance is required (YES), the process proceeds to step S3, and maintenance of the electron gun 102 is performed. If no maintenance is required (NO), the next step is step S6.

The maintenance method in the first embodiment is basically performed on the electron gun 102 that requires maintenance. However, it is difficult to determine whether the electron gun 102 really requires maintenance, and there is a case where the current performance of the electron gun 102 is to be checked. In such a case, “NO” is selected in step S2 and the process proceeds to step S6. Such a case will be described in more detail later.

In step S4, the inside of the electron gun 102 is made into a vacuum state. First, the inside of the electron gun 102 is vacuum evacuated by the diaphragm pump 114, so that the air pressure inside the electron gun 102 becomes 10⁻¹ Pa or lower than atmospheric pressure. Next, the inside of the electron gun 102 is vacuum evacuated by the turbo molecular pump 113, so that the air pressure inside the electron gun 102 becomes 10⁻¹ Pa to 10⁻⁴ Pa.

In step S5, the heat mechanism 306 is driven under the control of the drive mechanism 200, thereby performing a baking process on the entire electron gun 102. The baking process is performed at a heating temperature of 100° C. or higher for a specified period of time.

In step S6, the ion pump 301 is driven by controlling the ion pump power supply 115, thereby vacuum evacuating the inside of the electron gun 102 to make the inside of the electron gun 102 into an extremely high vacuum state (step S7).

In step S8, the electron beam 304 is started. Under the control of the high voltage power supply 201, an electron beam 304 is generated from the electron source 302, and the electron beam 304 is accelerated by applying a strong electric field from the acceleration electrode 303. As a result, the electron beam 304 is irradiated from the electron gun 102.

In step S9, the performance evaluation of the electron beam 304 is performed.

As an example of the performance evaluation, the measurement of the amount of the electron beam 304 will be described. When the electron beam 304 irradiated from the electron gun 102 is detected by the detector 117, the characteristics of the electron beam 304 are measured by the measuring device 118. For example, when the amount of the electron beam 304 is measured as the characteristics of the electron beam 304, it can be determined whether the amount of the electron beam 304 meets the specification criteria. The criteria for determination may be, in addition to the current value, the stability of the current, the energy of the electron beam 304, the amount of fluctuation of the electron beam 304, or the change in the degree of vacuum.

As another example of the performance evaluation, the focusing performance of the electron beam 304 is checked. By controlling the power supply 202 to drive the beam focusing mechanism 305, a magnetic field is generated from the beam focusing mechanism 305. The electron beam 304 is focused by the magnetic field. With this, it is possible to determine whether the focusing performance of the electron beam 304 meets the specification criteria. In addition, the optical axis of the electron beam 304 can be adjusted. Furthermore, it is possible to keep the vacuum state until step S10, and it is possible to store the electron gun 102 after checking its performance.

If the result of the performance evaluation in step S9 meets the specification criteria, step S10 is performed. After step S9, the inside of the evaluated electron gun 102 is maintained in an extremely high vacuum state by closing the valve 307.

In step S10, the transport package 100 including the evaluated electron gun 102 is transported to the vicinity of the second SEM device that requires maintenance. The electron gun 102 provided in the second SEM device is replaced with the evaluated electron gun 102. After that, the second SEM device is restarted (step S11).

As for the electron gun 102 provided in the second SEM device, steps S1 to S9 will be performed and the performance evaluation will be performed until the next maintenance. After that, the evaluated electron gun 102 can be provided in another SEM device that needs to replace the electron gun 102, thereby facilitating rapid restart.

In step S12, the second SEM device performs realignment of the optical axis to align the electron beam 304 with the optical axis of the electron gun 102. The optical axis is adjusted in step S9. However, when the evaluated electron gun 102 is mounted on the second SEM device, the optical axis may be misaligned due to a change in weight balance, or the like, and thus the optical axis is adjusted again in the second SEM device for checking. After that, the second SEM device can be used normally (step S13).

As described above, in the first embodiment, in the transport package 100 located outside the SEM device, start-up and performance evaluation of the electron gun 102 are performed. Therefore, the performance and safety of the electron gun 102 can be checked before being mounted in the SEM device.

Since steps S1 to S9 can be performed in the vicinity of the SEM device, the electron gun 102 can be replaced quickly. Moreover, steps S1 to S9 do not necessarily have to be performed in the vicinity of the SEM device, but may be performed at a location somewhat distant from the SEM device. Since the transport package 100 is movable, the evaluated electron gun 102 can be quickly transported to the vicinity of the SEM device in which the electron gun 102 needs to be replaced, and the electron gun 102 can be replaced. Therefore, the time required to restart the SEM device can be shortened, and the operating rate of the SEM device can be improved.

Also, steps S1 to S9 may be performed at a service station or an assembly manufacturing line that is physically separated from the SEM device.

### When Maintenance is Not Required

For example, there may be a case where the SEM device is experiencing some kind of malfunction and it is suspected that maintenance of the electron gun 102 is required. In such a case, the transport package 100 can also quickly check the current performance of the electron gun 102 to see if maintenance of the electron gun 102 is actually required. In such a case, “NO” is selected in step S2 and the process proceeds to step S6.

In the case of step S6, the valve 307 is kept closed, and the inside of the electron gun 102 is not exposed to atmospheric pressure and is kept in a vacuum state. Therefore, without using the turbo molecular pump 113 or the like, the ion pump 301 is driven in step S6, and the inside of the electron gun 102 is made into an extremely high vacuum state in step S7. After the valve 307 is opened, the electron beam 304 is quickly started up in step S8, and the performance evaluation of the electron beam 304 is performed in step S9. In this way, the current performance evaluation of the electron gun 102 can be performed in a short time by not performing steps S3 to S5.

If the results of the performance evaluation do not satisfy the specification criteria, it is determined that maintenance is necessary, and steps S3 to S9 are performed for that electron gun 102. If the results of the performance evaluation satisfy the specification criteria, it is determined that no maintenance is required, and the valve 307 can be closed and the electron gun 102 can be returned to the original SEM device for use.

As an example of improving the operating rate of the SEM device, there is a method for mounting the electron gun 102 on the SEM device with the high voltage power supply 201 and a cable connecting the high voltage power supply 201 and the electron gun 102 attached to the electron gun 102. This makes it possible to skip the axis alignment process after mounting the electron gun 102 on the SEM device. In addition, after the electron gun 102 is mounted on the SEM device, it becomes possible to immediately obtain an observation image by the SEM device.

In the first embodiment, the high voltage power supply 201 is exemplified, but the power supply is not limited to the high voltage power supply 201. Furthermore, the cables are not limited to those connecting the high voltage power supply 201 and the electron gun 102, and may include all cables connected to the electron gun 201.

### FIRST MODIFICATION

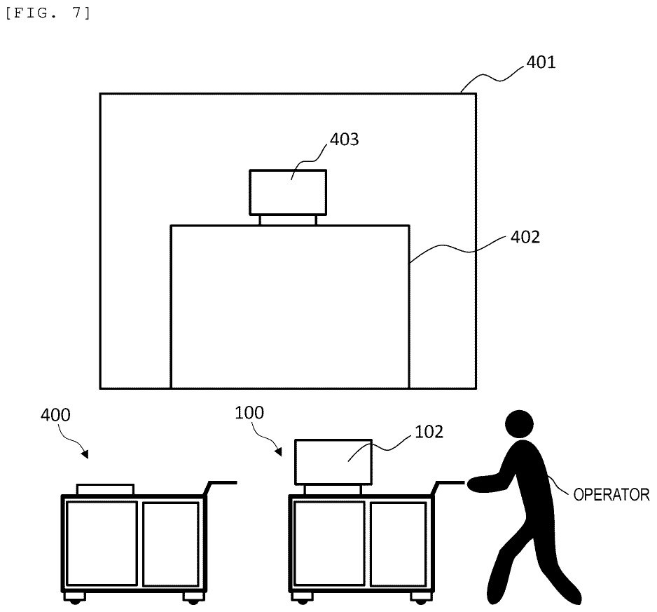

A maintenance method for a charged particle gun in a first modification of the first embodiment will be described below with reference to FIG. 6. In the following description, differences from FIG. 5 of the first embodiment will be mainly described, and descriptions of points that overlap with the first embodiment will be omitted.

In the first modification, when it is determined that there is some abnormality in the electron gun 102 in a state where the electron gun 102 is mounted on the SEM device, the electron gun 102 is mounted on the transport package 100, and maintenance of the electron gun 102, a baking process, and performance evaluation of the electron gun 102 or the performance evaluation of the electron beam 304 are performed.

As illustrated in FIG. 6, in step S61, it is determined whether maintenance is required for the electron gun 102 installed in the SEM device. If the maintenance is required (YES), the process proceeds to step S62 and the electron gun 102 is installed in the transport package 100. Then, the process proceeds to step S3, and maintenance of the electron gun 102 is performed.

On the other hand, if no maintenance is required (NO), the process proceeds to step S63, and the electron gun 102 is installed in the transport package 100. Then, the process proceeds to step S6, the ion pump 301 is driven to perform the performance evaluation of the electron gun 102 or the performance evaluation of the electron beam 304.

In FIG. 6, it is possible to perform only the necessary maintenance based on an abnormality that occurs in the state where the electron gun 102 is mounted on the SEM device, thereby making it possible to shorten the operation time.

### SECOND MODIFICATION

A transport package for a charged particle gun in a second modification of the first embodiment and a maintenance method for a charged particle gun will be described below with reference to FIG. 7. In the following description, differences from the first embodiment will be mainly described, and descriptions of points that overlap with the first embodiment will be omitted.

In the maintenance method for the charged particle gun of the second modification, when the electron gun 403 that is thought to require maintenance is removed from the SEM device and the evaluated electron gun 102 is mounted on the SEM device, two or more transport packages are used.

As illustrated in FIG. 7, an SEM device 401 includes a housing 402 of the SEM device 401 and an electron gun 403. A transport package 100 and one or more transport packages 400 different from the transport package 100 are prepared. The configuration of the transport package 100 is as described in the first embodiment. The configuration of transport package 400 is preferably the same as that of transport package 100, but may be different from that of transport package 100.

In the second modification, first, the transport package 100 including the evaluated electron gun 102, the inside of which is kept in a vacuum state, and one or more transport packages 400 are transported in the vicinity of the SEM device 401. Next, the electron gun 403 provided in the SEM device 401 is installed in one of the one or more transport packages 400. Next, the electron gun 102 is mounted from the transport package 100 into the housing 402 of the SEM device 401. Thereafter, among the one or more transport packages 400, steps S1 to S13 in FIG. 5 are performed in the transport package 400 in which the electron gun 403 is installed.

In this way, in the second modification, by using two or more transport packages 100, 400, it is possible to shorten the operation time compared to the operation performed using only one transport package 100 as in the first embodiment.

In the second modification, the configuration of the transport package 400 is the same as that of the transport package 100. However, some configurations of one or more transport packages 400 may differ from the configuration of the transport package 100. For example, some of the transport packages 400 be used exclusively for transporting electron guns. In that case, the part of the transport package 400 includes the installation unit 103 and the vacuum evacuation equipment 104, but may not include the evaluation equipment 105.

Although the invention has been specifically described based on the above embodiments, the invention is not limited to the above embodiments and can be modified in various ways without departing from the gist of the invention.

For example, in the above embodiments, an SEM device is given as an example of a charged particle device having a charged particle gun mounted thereon, but such a charged particle device may be a transmission electron microscope (TEM), a scanning transmission electron microscope (STEM), or an FIB-SEM device capable of irradiating a focused ion beam (FIB).

### REFERENCE SIGNS LIST

100: transport package
101: mobile equipment
102: electron gun (charged particle gun)
103: installation unit
104: vacuum evacuation equipment
105: evaluation equipment
106: caster
107: protective cover
111,112: pipe
113: turbo molecular pump
114: diaphragm pump
115: ion pump power supply
116: backup battery
117: detector
118: measuring device
200: drive mechanism for heat mechanism
201: high voltage power supply
202: power supply (constant current power supply or constant voltage power supply)
300: housing
301: ion pump
302: electron source (charged particle source)
303: acceleration electrode
304: electron beam (charged particle beam)
305: beam focusing mechanism
306: heat mechanism
307: valve
400: transport package
401: SEM device (charged particle beam device)
402: housing of SEM device
403: electron gun (charged particle gun)

1. A transport package for a charged particle gun, comprising:
an installation unit that installs a charged particle gun therein;
vacuum evacuation equipment that makes an inside of the charged particle gun into a vacuum state, in a state where the charged particle gun is installed in the installation unit; and
evaluation equipment that evaluates at least one of performance of the charged particle gun or performance of a charged particle beam irradiated from the charged particle gun in the state where the charged particle gun is installed in the installation unit,
wherein in the state where the charged particle gun is installed in the installation unit, the installation unit, the vacuum evacuation equipment, and the evaluation equipment are moved together.

2. The transport package for a charged particle gun according to claim 1, further comprising:
mobile equipment that has the installation unit, the vacuum evacuation equipment, and the evaluation equipment mounted thereon, and moves the installation unit, the vacuum evacuation equipment, and the evaluation equipment in the state where the charged particle gun is installed in the installation unit.

3. The transport package for a charged particle gun according to claim 1,
wherein the vacuum evacuation equipment includes at least one of a diaphragm pump, a turbo molecular pump, an ion pump, and a getter pump that vacuum evacuates the inside of the charged particle gun.

4. The transport package for a charged particle gun according to claim 1,
wherein the charged particle gun includes a heat mechanism,
the evaluation equipment includes a drive mechanism for the heat mechanism,
when the charged particle gun is installed in the installation unit, the drive mechanism is electrically connected to the heat mechanism, and
by controlling the drive mechanism to drive the heat mechanism, temperature of the entire charged particle gun is adjusted.

5. The transport package for a charged particle gun according to claim 1,
wherein the charged particle gun includes an ion pump,
the vacuum evacuation equipment includes an ion pump power supply,
when the charged particle gun is installed in the installation unit, the ion pump power supply is electrically connected to the ion pump, and
by controlling the ion pump power supply to drive the ion pump, the inside of the charged particle gun is vacuum evacuated.

6. The transport package for a charged particle gun according to claim 1,
wherein the charged particle gun includes a getter pump.

7. The transport package for a charged particle gun according to claim 1,
wherein the charged particle gun includes a charged particle source and an acceleration electrode,
the evaluation equipment includes a high voltage power supply,
when the charged particle gun is installed in the installation unit, the high voltage power supply is electrically connected to the charged particle source and the acceleration electrode, and
the charged particle beam is generated from the charged particle source by controlling the high voltage power supply, the charged particle beam is accelerated by applying a strong electric field to the acceleration electrode, and the charged particle beam is irradiated from the charged particle gun.

8. The transport package for a charged particle gun according to claim 7,
wherein the installation unit includes a detector that detects the charged particle beam, and a measuring device that is electrically connected to the detector, and
when the charged particle beam irradiated from the charged particle gun is detected by the detector, characteristics of the charged particle beam are measured by the measuring device.

9. The transport package for a charged particle gun according to claim 7,
wherein the charged particle gun includes a beam focusing mechanism that focuses the charged particle beam,
the evaluation equipment includes a constant current power supply or a constant voltage power supply,
when the charged particle gun is installed in the installation unit, the constant current power supply or the constant voltage power supply is electrically connected to the beam focusing mechanism, and
by controlling the constant current power supply or the constant voltage power supply to drive the beam focusing mechanism, a magnetic field is generated from the beam focusing mechanism, and the charged particle beam is focused by the magnetic field.

10. The transport package for a charged particle gun according to claim 1,
wherein the charged particle gun includes a valve that is controlled to be opened or closed between the inside of the charged particle gun and an inside of the installation unit, and
in a case where the valve is opened, the inside of the charged particle gun is made into a vacuum state by the vacuum evacuation equipment, and the charged particle beam irradiated from the charged particle gun reaches the inside of the installation unit.

11. The transport package for a charged particle gun according to claim 1, further comprising:
a protective cover that covers the installation unit, the vacuum evacuation equipment, and the evaluation equipment, and is attached to and detached from the installation unit, the vacuum evacuation equipment, and the evaluation equipment,
wherein when the charged particle gun is installed in the installation unit, the protective cover also covers the charged particle gun.

12. A maintenance method for a charged particle gun, the method comprising the steps of:
(a) transporting a transport package including a second charged particle gun, of which an inside is maintained in a vacuum state, to a vicinity of a first charged particle beam device;
(b) after the step (a), replacing a first charged particle gun provided in the first charged particle beam device with the second charged particle gun;
(c) after the step (b), installing the first charged particle gun in the transport package;
(d) after the step (c), making an inside of the first charged particle gun into a vacuum state in the transport package; and
(e) after the step (d), performing performance evaluation of a first charged particle beam irradiated from the first charged particle gun or performance evaluation of the first charged particle gun in the transport package.

13. A maintenance method for a charged particle gun, the method comprising the steps of:
(a) transporting a first transport package including a second charged particle gun, of which an inside is maintained in a vacuum state, and one or more transport packages other than the first transport package, to a vicinity of a first charged particle beam device;
(b) after the step (a), installing a first charged particle gun provided in the first charged particle beam device in any one of the one or more transport packages;
(c) after the step (b), mounting the second charged particle gun on the first charged particle beam device from the first transport package;
(d) after the step (c), making the inside of the first charged particle gun into a vacuum state in the transport package having the first charged particle gun installed therein, among the one or more transport packages; and
(e) after the step (d), performing performance evaluation of a first charged particle beam irradiated from the first charged particle gun or performance evaluation of the first charged particle gun, in the transport package having the first charged particle gun installed therein.

14. The maintenance method for a charged particle gun according to claim 12, the method further comprising the steps of:
(f) after the step (e), transporting the transport package having the first charged particle gun installed therein to a vicinity of a second charged particle beam device; and
(g) after the step (f), replacing a third charged particle gun provided in the second charged particle beam device with the first charged particle gun,
wherein when a result of the performance evaluation of the first charged particle beam performed in the step (e) meets specification criteria, the step (f) and the step (g) are performed.

15. The maintenance method for a charged particle gun according to claim 14, further comprising:
(h) after the step (g), performing realignment of an optical axis to align the first charged particle beam with an optical axis of the first charged particle gun, in the second charged particle beam device.

16. The maintenance method for a charged particle gun according to claim 12,
wherein the transport package includes
an installation unit that installs a charged particle gun therein,
vacuum evacuation equipment that makes the inside of the charged particle gun into a vacuum state, in a state where the charged particle gun is installed in the installation unit; and
evaluation equipment that evaluates at least one of performance of the charged particle gun or performance of a charged particle beam irradiated from the charged particle gun in the state where the charged particle gun is installed in the installation unit,
wherein the transport package moves the installation unit, the vacuum evacuation equipment, and the evaluation equipment all together in the state where the charged particle gun is installed in the installation unit.

17. The maintenance method for a charged particle gun according to claim 16,
wherein the transport package further includes mobile equipment that has the installation unit, the vacuum evacuation equipment, and the evaluation equipment mounted thereon, and moves the installation unit, the vacuum evacuation equipment, and the evaluation equipment in the state where the charged particle gun is installed in the installation unit.
